(19) United States
(12) Patent Application Publication
(10) Pub. No.: US 2024/0243094 A1
(43) Pub. Date: Jul. 18, 2024

(54) BONDING METHOD, BONDING APPARATUS, ARTICLE MANUFACTURING METHOD, DETERMINATION METHOD, INFORMATION PROCESSING APPARATUS, AND STORAGE MEDIUM

(71) Applicant: CANON KABUSHIKI KAISHA, Tokyo (JP)

(72) Inventors: MASAHIRO KIMURA, Tochigi (JP); KENICHIRO MORI, Tochigi (JP)

(21) Appl. No.: 18/403,011

(22) Filed: Jan. 3, 2024

(30) Foreign Application Priority Data
Jan. 17, 2023 (JP) 2023-005316

(51) Int. Cl. H01L 23/00; H01L 25/00

(52) U.S. Cl. CPC H01L 24/75; H01L 24/81; H01L 25/50; H01L 25/0652; H01L 2224/75001; H01L 2224/75701; H01L 2224/75702; H01L 2224/75753; H01L 2224/81132

(57) ABSTRACT

The present invention provides a bonding method of bonding each of a plurality of first objects to a first substrate, comprising: determining, as an offset amount, an amount to offset a bonding position on the first substrate from a design position for each of the plurality of first objects; and bonding each of the plurality of first objects to the first substrate based on the offset amount determined in the determining, wherein after the bonding, a process of bonding a plurality of second objects which are bonded to a second substrate, to the plurality of first objects bonded to the first substrate is performed, and wherein in the determining, the offset amount is determined to satisfy a predetermined condition based on arrangement information representing an arrangement of the plurality of second objects on the second substrate.

### BACKGROUND OF THE INVENTION

### Field of the Invention

The present invention relates to a bonding method, a bonding apparatus, an article manufacturing method, a determination method, an information processing apparatus, and a storage medium.

### Description of the Related Art

Japanese Patent Laid-Open No. 2019-129165 proposes a method of bonding two substrates. In the method described in Japanese Patent Laid-Open No. 2019-129165, at least a part of a second substrate is bonded to at least a part of a first substrate held by a holder, and after that, the first substrate and the second substrate are bonded to extend a bonding region.

In recent years, a technique has received a great deal of attention, in which after a plurality of first objects (dies) are bonded to a first substrate, and a plurality of second objects (dies) are bonded to a second substrate, the plurality of first objects bonded to the first substrate and the plurality of second objects bonded to the second substrate are bonded to each other. In this technique, a plurality of sets of one first object and one second object, which are electrically connected, are formed. However, if the arrangement of the plurality of first objects on the first substrate and the arrangement of the plurality of second objects on the second substrate are deviated from each other, a set of a first object and a second object with an electrical connection failure may be formed.

### SUMMARY OF THE INVENTION

The present invention provides a technique advantageous in, for example, reducing electrical connection failures when a plurality of first objects bonded to a first substrate and a plurality of second objects bonded to a second substrate are bonded to each other.

According to one aspect of the present invention, there is provided a bonding method of bonding each of a plurality of first objects to a first substrate, comprising: determining, as an offset amount, an amount to offset a bonding position on the first substrate from a design position for each of the plurality of first objects; and bonding each of the plurality of first objects to the first substrate based on the offset amount determined in the determining, wherein after the bonding, a process of bonding a plurality of second objects which are bonded to a second substrate, to the plurality of first objects bonded to the first substrate is performed, wherein in the determining, the offset amount is determined to satisfy a predetermined condition based on arrangement information representing an arrangement of the plurality of second objects on the second substrate, and wherein the predetermined condition includes a first condition to electrically connect each of the plurality of first objects and the first substrate after the bonding is performed, and a second condition to electrically connect each of the plurality of first objects and a corresponding one of the plurality of second objects after the process is performed.

Further features of the present invention will become apparent from the following description of exemplary embodiments with reference to the attached drawings.

### BRIEF DESCRIPTION OF THE DRAWINGS

FIG. 1 is a schematic view showing a bonding apparatus according to an embodiment of the present invention;

FIG. 2 is a view showing an example of the configuration of a wafer stage;

FIGS. 3A and 3B are schematic views showing a state in which an image of a die is captured and an example of the configuration of the die;

FIG. 4 is a flowchart showing the operation procedure of the bonding apparatus according to the embodiment of the present invention;

FIG. 5 is a flowchart showing an offset amount determination method;

FIGS. 6A and 6B are views showing a plurality of design positions on each of a first wafer and a second wafer;

FIGS. 7A to 7C are views for explaining an offset amount;

FIGS. 8A to 8C are views for explaining an offset amount;

FIGS. 9A to 9C are views for explaining an offset amount; and

FIG. 10 is a view showing the relationship between a die position deviation amount and a design position deviation amount.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the surface (bonding surface) of a first substrate are defined as the X-Y plane. Directions parallel to the X-axis, the Y-axis, and the Z-axis of the XYZ coordinate system are defined as the X direction, the Y direction, and the Z direction, respectively. A rotation about the X-axis, a rotation about the Y-axis, and a rotation about the Z-axis are defined as θX, θY, and θZ, respectively. Control and driving (movement) concerning the X-axis, the Y-axis, and the Z-axis mean control or driving (movement) concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively.

In embodiments to be described later, an example in which a wafer (substrate) on which semiconductor devices are formed is used as a first substrate, and a die (chip) obtained by dividing into pieces a wafer on which semiconductor devices are formed is used as a first object to be bonded will be explained. However, the first substrate and the first object are not limited to these, and various changes and modifications can be made within the scope of the present invention. Examples of the first substrate are a silicon wafer, a silicon wafer on which wirings are formed, a glass wafer, a glass panel on which wirings are formed, an organic panel (PCB) on which wirings are formed, and a metal panel, in addition to a wafer on which semiconductor devices are formed. The first substrate may be a wafer to which one or more dies are already bonded. Also, examples of the first object are a stack of dies, a small piece of a material, an optical element, a MEMS, and a structure, in addition to a die obtained by dividing into pieces a wafer on which semiconductor devices are formed.

In the embodiments to be described later, various temporary or permanent bonding methods can be applied as a bonding method for the first substrate and the first object. Examples of the bonding method are bonding using an adhesive, temporary bonding using a temporary adhesive, bonding by hybrid bonding, atomic diffusion bonding, vacuum bonding, and bump bonding.

Industrial application examples of the embodiments to be described later will be explained next.

The first application example is manufacturing of a stacked memory. In a case where a bonding apparatus according to the embodiments to be described later is applied to manufacturing of a stacked memory, a wafer (substrate) on which a memory serving as a semiconductor device is formed is used as the first substrate, and a die (chip) on which a memory is formed is used as the first object. For example, in manufacturing of a stacked memory having eight memory layers, the first object (die) formed as the eighth memory layer is bonded on the first substrate already having seven memory layers. Note that the final layer of the stacked memory may be not a memory layer but a layer on which a driver for driving the memory is formed.

The second application example is heterogeneous integration of a processor. The mainstream of conventional processors is a System On Chip (SoC) in which a logic circuit, a Static Random Access Memory (SRAM), and the like are formed in one semiconductor element. To the contrary, in heterogeneous integration, a plurality of types of elements are formed from separate wafers by applying a process optimal for each element, and bonded to manufacture a processor. This can implement cost reduction and yield improvement of processors. In a case where the bonding apparatus according to the embodiment to be described later is applied to heterogeneous integration, a wafer (substrate) on which a logic device serving as a semiconductor device is formed is used as the first substrate. A die (chip) separated after probing, such as an SRAM, an antenna, or a driver, is used as the first object. In heterogeneous integration, for example, dies of different types are sequentially bonded, so bonded objects to the first substrate sequentially increase. More specifically, when a die having an SRAM is bonded onto a logic wafer, the logic wafer is the first substrate and the die having the SRAM is the first object. When a die having an element to be formed on the SRAM is bonded onto the die having the SRAM, a die having a logic wafer and an SRAM is the first substrate, and the die having the element is the first object.

The third application example is 2.5D bonding using a silicon interposer. The silicon interposer is a silicon wafer on which wirings are formed. The 2.5D bonding is a method of bonding a plurality of types of dies onto the silicon interposer, and electrically connecting the plurality of types of dies by the wirings on the silicon interposer. In a case where the bonding apparatus according to the embodiment to be described later is applied to the 2.5D bonding, a silicon wafer on which wirings are formed is used as the first substrate, and a separated die is used as the first object. In the 2.5D bonding, for example, a plurality of types of dies are bonded to the silicon interposer, so the structure of a silicon interposer to which one or more dies are already bonded is sometimes handled as the first substrate.

The fourth application example is 2.1D bonding using an organic interposer or a glass interposer. The organic interposer is an organic panel (a PCB substrate or a CCL substrate) used as a package substrate, on which wirings are formed. The glass interposer is a glass panel on which wirings are formed. The 2.1D bonding is a method of bonding a plurality of types of dies to the organic interposer or the glass interposer, and electrically bonding the plurality of types of dies by the wirings on the interposer. In a case where the bonding apparatus according to the embodiment to be described later is applied to the 2.1D bonding, in 2.1D bonding using the organic interposer, an organic panel on which wirings are formed is used as the first substrate, and a separated die is used as the first object. To the contrary, in 2.1D bonding using the glass interposer, a glass panel on which wirings are formed is used as the first substrate, and a separated die is used as the first object. In the 2.1D bonding, for example, a plurality of types of dies are bonded to the organic interposer or the glass interposer, so the structure of an organic interposer or a glass interposer to which one or more dies are already bonded is sometimes handled as the first substrate.

The fifth application example is heterogeneous substrate bonding. For example, in an infrared image sensor, InGaAs known as a high-sensitivity material is used for a sensor unit configured to receive light, and silicon capable of implementing high-speed processing is used for a logic circuit configured to extract data. Accordingly, a high-sensitivity high-speed infrared image sensor can be manufactured. However, from InGaAs crystal, only wafers whose diameter is as small as 4 inches are mass-produced, which is smaller than a mainstream 300-mm silicon wafer. Hence, there has been proposed a method of bonding, to a 300-mm silicon wafer on which a logic circuit is formed, a die obtained by dividing an InGaAs substrate into pieces. The bonding apparatus according to the embodiment to be described later can also be applied to heterogeneous substrate bonding of bonding substrates made of different materials and having different sizes. In the application of the bonding apparatus to heterogeneous substrate bonding, a substrate with a large diameter such as a silicon wafer is used as the first substrate, and a die (small piece) of a material such as InGaAs is used as the first object. Note that the die (small piece) of the material such as InGaAs may be a slice of a crystal and is preferably cut into a rectangular shape.

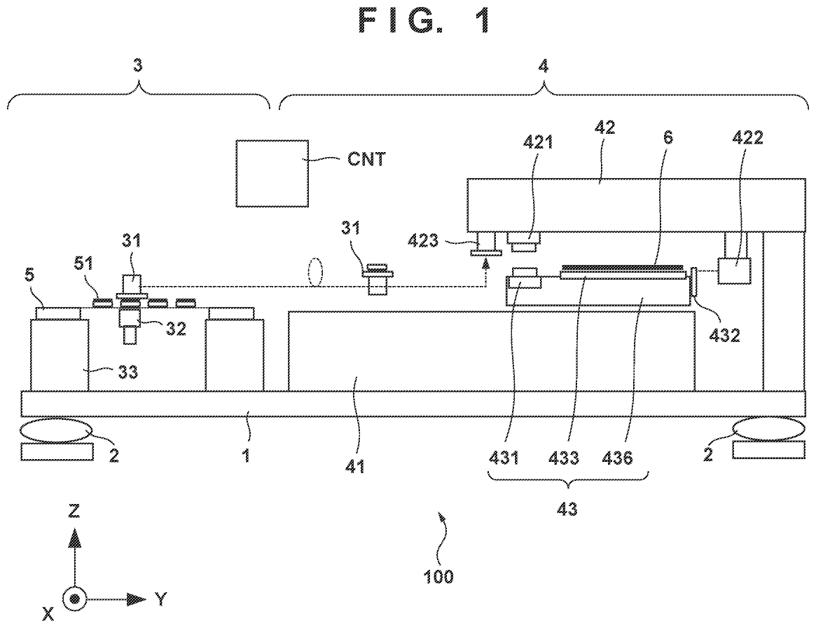

An embodiment according to the present invention will be described below. FIG. 1 is a schematic view showing a bonding apparatus 100 of an embodiment according to the present invention. In FIG. 1, a direction vertical to the upper surface of a first wafer 6 (first substrate) held by a wafer stage 43 is defined as the Z direction, and directions orthogonal to each other in a plane parallel to the upper surface of the first wafer 6 are defined as the X direction and the Y direction. The bonding apparatus 100 is an apparatus that sequentially bonds each of a plurality of first dies 51 as the first object to the first wafer 6 (first substrate) that is a first substrate. The plurality of first dies 51 are arranged on a dicing tape adhered to a dicing frame 5.

As shown in FIG. 1, the bonding apparatus 100 according to this embodiment includes a pickup unit 3, a bonding unit 4 (bonder), and a controller CNT. The pickup unit 3 and the bonding unit 4 are mounted on a base 1 damped by mounts 2. The pickup unit 3 and the bonding unit 4 are mounted on the same base 1 in this embodiment, but may be individually mounted on separate bases.

The pickup unit 3 includes a pickup head 31, a release head 32, and a frame holder 33. The pickup unit 3 picks up the first dies 51 one by one from the dicing tape adhered to the dicing frame 5. The frame holder 33 holds the dicing frame 5. The release head 32 pushes up the target first die 51 from the back side of the dicing tape adhered to the dicing frame 5 such that the target first die 51 to be picked up projects upward from the remaining dies. At this time, the target first die 51 is partially peeled from the dicing tape. The pickup head 31 holds (sucks) by a vacuum force or the like the target first die 51 pushed up by the release head 32, and peels (separates) the target first die 51 from the dicing tape. The pickup head 31 is configured to be movable from the pickup unit 3 to the bonding unit 4. During movement from the pickup unit 3 to the bonding unit 4, the pickup head 31 rotates (flip-chip) to turn over the first die 51 and transfers it to a bonding head 423 to be described later.

The bonding unit 4 includes a stage base 41 and an upper base 42, and the wafer stage 43 is mounted on the stage base 41. The wafer stage 43 is configured to hold the first wafer 6 and move on the stage base 41. More specifically, the wafer stage 43 includes a wafer chuck 433 that holds the first wafer 6 by a vacuum force or the like, and a driving mechanism 436 that drives the wafer chuck 433 (first wafer 6). The driving mechanism 436 includes an actuator such as a linear motor, and is configured to drive the first wafer 6 in the X and Y directions and the θZ direction (the rotational direction about the Z-axis). The driving mechanism 436 may be configured to drive the first wafer 6 in the Z direction. A relative rotational operation of the first wafer 6 and the first die 51 in the θZ direction can be performed by rotating the first wafer 6 by the wafer stage 43 (driving mechanism 436) and/or rotating the first die 51 by the bonding head 423.

The wafer stage 43 also includes a mirror 432 for measuring the position of the wafer stage 43 in the X and Y directions. The mirror 432 serves as the target of an interferometer 422 that measures the position of the wafer stage 43 in the X and Y directions. The interferometer 422 is mounted on the upper base 42, irradiates the mirror 432 provided on the wafer stage 43 with light, and measures the position of the wafer stage 43 based on reflected light from the mirror 432. The controller CNT can control the position of the wafer stage 43 (first wafer 6) in the X and Y directions and the θZ direction based on the position of the wafer stage 43 measured by the interferometer 422.

Also, a die observation camera 431 (die image capturing device) is mounted on the wafer stage 43. The die observation camera 431 is a camera for observing the bonding surface of the first die 51. The die observation camera 431 can be arranged so that it can capture an image of the bonding surface of the first die 51 in a state in which the first die 51 is held by the bonding head 423 (holder). In this embodiment, the die observation camera 431 is mounted on the wafer stage 43 (driving mechanism 436) and can move in the X and Y directions along with movement of the wafer stage 43. The die observation camera 431 is used to obtain (measure) information representing the position of a pattern provided on the bonding surface of the first die 51. For example, using a known image processing technique, the controller CNT detects the position of a feature point on the bonding surface of the first die 51 from an image obtained by capturing the bonding surface of the first die 51 by the die observation camera 431. Thus, the controller CNT can measure the position of the pattern of the first die 51 held by the bonding head 423 in the X and Y directions and/or the θZ direction.

Here, the die observation camera 431 can also be used to measure the distances of a plurality of points in the direction of height (Z direction) on the bonding surface of the first die 51, that is, the height distribution of the bonding surface of the first die 51. That is, the die observation camera 431 can be used to measure the position of the first die 51 held by the bonding head 423 in the direction of height, the tilt of the first die 51, and/or the flatness of the bonding surface. Note that in this embodiment, the pattern provided on the bonding surface of the first die 51 can be defined to include a circuit pattern and in addition, a mark for measuring the position of the first die 51.

Mechanisms mounted on the upper base 42 will be described next. The bonding head 423, a wafer observation camera 421, and the interferometer 422 are mounted on the upper base 42.

The bonding head 423 holds by a vacuum force or the like the first die 51 transferred from the pickup head 31, and drives the first die 51 in the -Z direction to bond the first die 51 to the first wafer 6. In this embodiment, bonding of the first die 51 to the first wafer 6 is performed by the bonding head 423 driving the first die 51 in the -Z direction. However, the present invention is not limited to this. For example, bonding of the first die 51 to the first wafer 6 maybe done by the wafer stage 43 driving the first wafer 6 in the +Z direction. Alternatively, bonding of the first die 51 to the first wafer 6 maybe done by relatively driving the first die 51 and the first wafer 6 by the bonding head 423 and the wafer stage 43.

The wafer observation camera 421 (wafer image capturing device) is a camera for observing the bonding surface of the first wafer 6. The wafer observation camera 421 can be arranged so that it can capture an image of the first wafer 6 in a state in which the first wafer 6 is held by the wafer stage 43. The wafer observation camera 421 is used to obtain (measure) information representing the position of a pattern provided on the bonding surface of the first wafer 6. For example, using a known image processing technique, the controller CNT detects the position of a feature point on the bonding surface of the first wafer 6 from an image obtained by capturing the bonding surface of the first wafer 6 by the wafer observation camera 421. Thus, the controller CNT can measure the position of the pattern of the first wafer 6 held by the wafer stage 43 in the X and Y directions and/or the θZ direction.

Here, the wafer observation camera 421 can also be used to measure the distances of a plurality of points in the direction of height (Z direction) on the bonding surface of the first wafer 6, that is, the height distribution of the bonding surface of the first wafer 6. That is, the wafer observation camera 421 can be used to measure the position of the first wafer 6 held by the stage 43 in the direction of height, the tilt of the first wafer 6, and/or the flatness of the bonding surface.

The controller CNT is formed from, for example, a computer (information processing apparatus) including a processor such as a Central Processing Unit (CPU) and a storage such as a memory. The controller CNT controls the bonding process by controlling each unit of the bonding apparatus 100. The bonding process is a process of aligning the first wafer 6 and the first die 51 and bonding the first die 51 to the first wafer 6. More specifically, the controller CNT obtains the position of the pattern provided on the bonding surface of the first wafer 6 based on an image of the bonding surface of the first wafer 6 that is captured by the wafer observation camera 421. Also, the controller CNT obtains the position of the pattern provided on the bonding surface of the first die 51 based on an image of the bonding surface of the first die 51 that is captured by the die observation camera 431. The controller CNT can control the bonding process based on the position of the pattern of the first wafer 6 and that of the pattern of the first die 51.

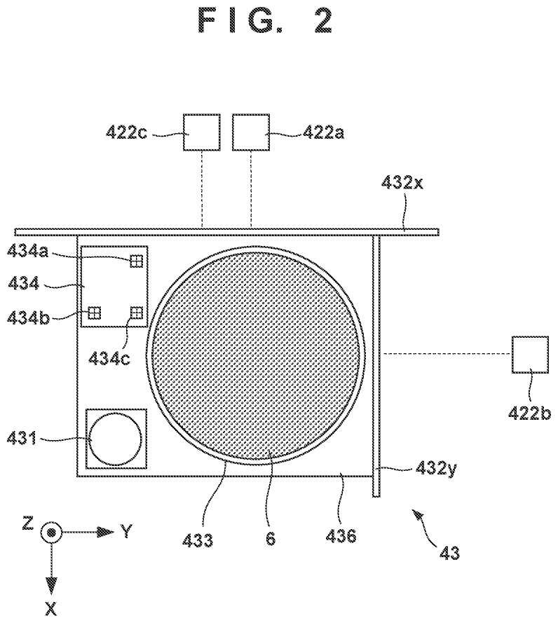

A detailed example of the configuration of the wafer stage 43 will be described next. FIG. 2 is a view showing the wafer stage 43 viewed from the +Z direction. The first wafer 6 is held by the wafer chuck 433. To perform two-dimensional positioning, the wafer stage 43 includes a bar mirror 432x for performing position measurement in the X direction and the θZ direction (rotational direction), and a bar mirror 432y for performing position measurement in the Y direction. The bar mirror 432x is the target of interferometers 422a and 422c that perform position measurement in the X direction. The interferometers 422a and 422c are arranged apart in the Y direction. The rotational amount (θZ direction) of the wafer stage 43 can be obtained from the difference between the measurement result of the interferometer 422a and that of the interferometer 422c. The bar mirror 432y is the target of an interferometer 422b that performs position measurement in the Y direction. The interferometers 422a to 422c measure in real time the position of the wafer stage 43 in the X direction, the position in the Y direction, and the rotational amount in the θZ direction. The controller CNT can perform feedback control of driving of the wafer stage 43 in real time and two-dimensionally position the wafer stage 43 accurately. In the bonding apparatus 100 according to this embodiment, accurate position measurement by the interferometers 422a to 422c, and feedback control of the driving mechanism of the wafer stage 43 based on the result of the position measurement can function as the positioning mechanism of the wafer stage 43.

A reference plate 434 including a plurality of marks 434a to 434c is mounted on the wafer stage 43. The reference plate 434 is made of a material with a low thermal expansion coefficient, and includes the marks 434a to 434c formed (drawn) at a high position accuracy. For example, the reference plate 434 can be formed by drawing marks on a quartz substrate using the drawing method of a semiconductor lithography process. The reference plate 434 can be arranged to have a surface substantially flush with the surface of the first wafer 6. In this embodiment, the reference plate 434 can be observed by the wafer observation camera 421, but the present invention is not limited to this when a reference plate observation camera is separately provided. The wafer stage 43 maybe constituted by a coarse motion stage that can be driven within a large range, and a fine motion stage that can accurately be driven within a small range on the coarse motion stage. In this case, the die observation camera 431, the mirror 432, the wafer chuck 433, and the reference plate 434 require accurate positioning and thus are preferably mounted (fixed) on the fine motion stage.

A method of guaranteeing the origin position, magnification, the X-axis and Y-axis directions (rotation), and the orthogonality of the wafer stage 43 using the reference plate 434 will be described. While controlling the wafer observation camera 421 to capture (observe) an image of the mark 434a, the controller CNT obtains the measured values of the interferometers 422a to 422c when the mark 434a is arranged at the center of the image obtained by the wafer observation camera 421. The obtained measured values are set as the origin of the wafer stage 43. Then, while controlling the wafer observation camera 421 to capture (observe) an image of the mark 434b, the controller CNT obtains the measured values of the interferometers 422a to 422c when the mark 434b is arranged at the center of the image obtained by the wafer observation camera 421. From the obtained measured values, the controller CNT decides the Y-axis direction and Y magnification of the wafer stage 43. Next, while controlling the wafer observation camera 421 to capture (observe) an image of the mark 434c, the controller CNT obtains the measured values of the interferometers 422a to 422c when the mark 434c is arranged at the center of the image obtained by the wafer observation camera 421. From the obtained measured values, the controller CNT decides the X-axis direction and X magnification of the wafer stage 43. That is, a direction from the mark 434b toward the mark 434a on the reference plate 434 is defined as the Y-axis of the bonding apparatus 100, a direction from the mark 434c toward the mark 434a is defined as the X-axis of the bonding apparatus 100, and the directions and orthogonality of the axes are calibrated. Also, the interval between the mark 434b and the mark 434a is defined as the scale reference of the bonding apparatus 100 in the Y direction, the interval between the mark 434c and the mark 434a is defined as the scale reference of the bonding apparatus 100 in the X direction, and calibration is performed. The refractive index of the optical path of the interferometer changes due to variations of the atmospheric pressure and temperature, this makes the measured value vary, and thus it is preferable for the interferometers 422a to 422c to perform calibration at an arbitrary timing and guarantee the origin position, magnification, rotation, and orthogonality of the wafer stage 43. Note that to reduce variations of the measured values of the interferometers 422a to 422c, the space in which the wafer stage 43 moves may be covered with a temperature control chamber to control the temperature.

In this embodiment, an example in which the reference plate 434 is arranged on the wafer stage 43 and an image of the reference plate 434 is captured (observed) by the wafer observation camera 421 has been described, but the present invention is not limited to this. For example, the reference plate 434 may be arranged on the upper base 42 to capture (observe) an image of the reference plate 434 by the die observation camera 431. Even in this configuration, the origin position, magnification, rotation, and orthogonality of the wafer stage 43 can be guaranteed. In this embodiment, an example in which calibration is performed by capturing (observing) an image of the reference plate 434 has been described, but the present invention is not limited to this. For example, calibration may be performed by an abutting operation to a reference surface. Alternatively, accurate positioning of the wafer stage 43 maybe performed using a position measurement means such as a white interferometer for which an absolute value is guaranteed.

### Operation of Bonding Apparatus

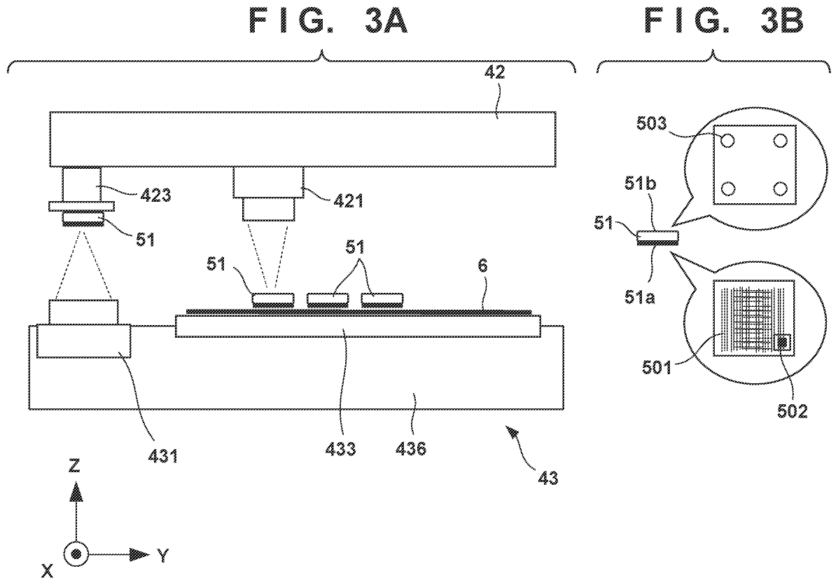

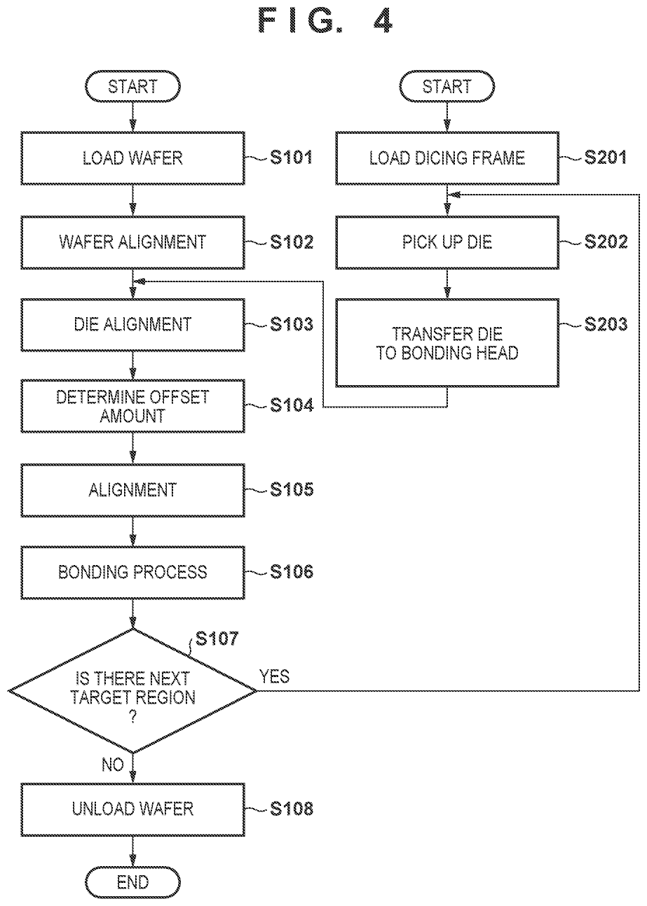

The operation of the bonding apparatus 100 according to this embodiment will be described next with reference to FIGS. 3A, 3B, and 4. FIG. 3A is a schematic view showing a state in which an image of the first die 51 is captured. FIG. 3B is a schematic view showing an example of the configuration of the first die 51. As shown in FIG. 3B, the first die 51 has a bonding surface 51a and a back surface 51b that is a surface opposite to the bonding surface. The bonding surface 51a of the first die 51 has an element pattern 501 and an alignment mark 502. It may be understood that the element pattern 501 includes electrodes (bumps) to be electrically connected to electrodes provided on the first wafer 6. Also, the back surface 51b of the first die 51 is provided with electrodes (bumps) 503 to be electrically connected to the electrodes of a second object (second die) bonded a second substrate (second wafer), as will be described later. Each electrode 503 is electrically connected, via a through via, to, for example, a part of a circuit (for example, the element pattern 501 formed on the bonding surface 51a) formed on the first die 51. Note that FIG. 3B shows an example in which four electrodes 503 are provided on the back surface 51b of the first die 51. However, the number of electrodes 503 provided on the back surface 51b is not limited to four, and may be one to three, or five or more.

FIG. 4 is a flowchart showing the operation procedure of the bonding apparatus 100 according to this embodiment. The controller CNT can execute processes in the flowchart of FIG. 4.

In step S101, the controller CNT loads the first wafer 6 serving as a first substrate onto the wafer stage 43 (chuck 433) using a wafer conveyance mechanism (not shown). At this time, the space in the bonding apparatus 100 is desirably kept at a high cleanliness of about class 1 because adhesion of a foreign substance to the bonding surface of the first wafer 6 causes a bonding failure. To maintain a high level of cleanliness even for the first wafer 6, the first wafer 6 is desirably stored in a container that has a high airtightness and maintains a high cleanliness, and conveyed from the container onto the wafer stage 43. The container is, for example, a Front Opening Unify Pod (FOUP).

To increase the cleanliness of the first wafer 6, a washing mechanism that washes the first wafer 6 maybe provided in the bonding apparatus 100. A mechanism that performs a preprocess for the bonding process on the first wafer 6 may also be provided in the bonding apparatus 100. For example, the preprocess is a process of applying an adhesive to the bonding surface of the first wafer 6 in bonding using an adhesive, or a process of activating the bonding surface of the first wafer 6 in hybrid bonding. After positions of the first wafer 6 in the θZ direction and the X and Y directions are measured by a prealignment unit (not shown), the first wafer 6 is coarsely positioned based on the measurement result and conveyed onto the chuck 433 of the stage 43. The position of the first wafer 6 in the θZ direction can be measured by detecting a notch or orientation flat of the first wafer 6, and the position of the first wafer 6 in the X and Y directions can be measured by detecting the outer shape of the first wafer 6.

In step S102, the controller CNT performs wafer alignment using the wafer observation camera 421. In the wafer alignment, the wafer observation camera 421 captures an image of the bonding surface of a target region (bonding goal) of the first wafer 6 to which the first die 51 is to be bonded. Based on the obtained image, the position of a pattern provided on the first wafer 6 (target region) is obtained. The target region may be understood as a design position to bond the first die 51 on the first wafer 6. A plurality of target regions to bond the plurality of first dies 51 (first objects) are set in advance on the first wafer 6.

Focus adjustment when capturing an image of the bonding surface of the first wafer 6 maybe performed by the focus adjustment mechanism of the wafer observation camera 421, or by driving the first wafer 6 in the Z direction by the Z driving mechanism of the wafer stage 43. When an alignment mark is provided on the bonding surface of the first wafer 6, the position of the pattern of the first wafer 6 can be obtained using the alignment mark. To the contrary, when no alignment mark is provided on the bonding surface of the first wafer 6, the position of the pattern of the first wafer 6 maybe obtained using a portion (to be sometimes referred to as a specifiable portion hereinafter) of the target inspection surface that allows specifying the position of the pattern. As the specifiable portion, for example, part of the pattern of the first wafer 6 can be used.

For example, the controller CNT can measure the position of the pattern of the first wafer 6 by measuring the image position of an alignment mark or specifiable portion with respect to the center of the image obtained by the wafer observation camera 421. The alignment mark or specifiable portion will sometimes be referred to as an alignment mark or the like hereinafter. For example, there is a method of accurately measuring the position of the alignment mark or the like with respect to the reference point of the bonding apparatus 100. According to this method, the stage 43 is driven to make a mark formed on the reference plate 434 fall within the visual field of image capturing of the wafer observation camera 421, and the wafer observation camera 421 captures an image of the mark on the reference plate 434. Based on the position of the stage 43 at that time and the mark position within the image obtained by the wafer observation camera 421, the reference point of the bonding apparatus 100 is determined. Based on the image obtained by capturing the alignment mark or the like by the wafer observation camera 421, the positional relationship of the alignment mark or the like with respect to the reference point is obtained. Hence, the position of the alignment mark can be measured accurately from the position of the reference point and the positional relationship. As the position of the reference point of the bonding apparatus 100, the position of the mark on the reference plate 434 is used. However, the position of another place may be used if it is a position serving as a reference.

Since the interferometer 422 has a narrow measurement range in the θZ direction, a rotation amount in the θZ direction that can be corrected by the wafer stage 43 is relatively small. If the rotation amount of the first wafer 6 in the θZ direction is large, the first wafer 6 is preferably rearranged on the wafer stage 43 so as to correct the rotation amount of the first wafer 6 in the θZ direction. When the first wafer 6 is rearranged on the wafer stage 43, the position of the first wafer 6 needs to be measured again. During execution of step S102, the surface position of the first wafer 6 is preferably measured using a first height measurement means (not shown) that measures the surface position of the bonding surface of the first wafer 6. This is because the thickness of the first wafer 6 varies, and the surface position of the first wafer 6 is important to accurately manage (control) the gap between the first wafer 6 and the first die 51 in the bonding process.

The origin position, the magnification, the position in the X and Y directions, rotation in the θZ direction, and the orthogonality are guaranteed for the wafer stage 43 using the reference plate 434. For this reason, the position of the first wafer 6 mounted on the stage 43 with respect to the origin position of the wafer stage 43 and the like can be measured. On the first wafer 6, target regions (bonding goals or goal regions) where semiconductor devices are formed are repetitively arranged at a predetermined period in the first wafer 6. That is, the first wafer 6 includes a plurality of target regions to which the first dies 51 are bonded, respectively. Since a semiconductor device in each target region is accurately positioned and manufactured using a semiconductor manufacturing apparatus, the plurality of target regions on the first wafer 6 are accurately arrayed generally at a repetitive period with a nano-level accuracy. Hence, in the wafer alignment of step S102, it is not necessary to measure the positions of all target regions on the first wafer 6, and it is only necessary to measure the positions of some of the plurality of target regions on the first wafer 6. More specifically, the positions of semiconductor devices (patterns or marks) in three or more target regions out of a plurality of target regions on the first wafer 6 are measured, and statistical processing is performed. Accordingly, the array of target regions, the origin position of the array, the position in the X and Y directions, the rotation amount in the θZ direction, the orthogonality, and the magnification error of the repetitive period can be calculated.

The chuck 433 may include a mechanism that controls the temperature of the first wafer 6. This is because in a case where the thermal expansion coefficient of a silicon wafer is 3 ppm/° C., and the diameter of the wafer is 300 mm, if the temperature increases by 1° C., the position of the outermost periphery moves by 150 mm×0.000003=0.00045 mm=450 nm. If a bonding position (for example, the position of the target region) moves after wafer alignment, it may be difficult to accurately bond the first wafer 6 and the first die 51. Thus, the temperature of the first wafer 6 is preferably controlled to keep the temperature change of the first wafer 6 to be 0.1° C. or less.

Note that in this embodiment, the wafer is used as the first substrate. If an interposer on which wirings are formed is used as the first substrate, not the array of semiconductor devices but the array of the repetitively formed wirings is measured. If a wafer or panel without a pattern is used as the first substrate, wafer alignment in step S102 need not be executed.

Steps S101 and S102 described above are processes regarding the first wafer 6 serving as the first substrate. On the other hand, in parallel to steps S101 and S102, processes (steps S201 to S203) regarding the first die 51 serving as the first object are executed.

In step S201, the controller CNT loads the dicing frame 5 to the pickup unit 3 (onto the frame holder 33) using a conveyance mechanism (not shown). The dicing frame 5 is a frame having an opening at the center, and a dicing tape is adhered to the dicing frame 5 so as to cover the opening. The plurality of first dies 51 divided by a cutter such as a dicer are arrayed on the dicing tape. Conventionally, the dicing frame 5 is conveyed by an unsealed magazine. However, adhesion of a foreign substance to the bonding surface 51a of the first die 51 causes a bonding failure, so the dicing frame 5 needs to be conveyed in a container that has a high airtightness and maintains a high cleanliness. Here, to increase the cleanliness of the first die 51, a washing mechanism that washes the first die 51 on the dicing frame 5 (dicing tape) may be provided inside the bonding apparatus 100. After the rotation of the dicing frame 5 in the θZ direction and the shift position (position in the X and Y directions) of the dicing frame 5 are coarsely determined by a prealignment unit (not shown) based on the outer shape of the dicing frame 5, the dicing frame 5 can be conveyed onto the frame holder 33.

In step S202, the controller CNT controls the pickup head 31 and the release head 32 to pick up one first die 51 from the dicing frame 5 (dicing tape). More specifically, the controller CNT moves the pickup head 31 and the release head 32 to the position of the first die 51 to be picked up (to be also referred to as the target first die 51 hereinafter). The controller CNT drives the release head 32 in the +Z direction to push up the target first die 51 from the back side of the dicing tape. In this state, the controller CNT drives the pickup head 31 in the −Z direction to bring the pickup head 31 and the target first die 51 into contact with each other. The target first die 51 is then held (sucked) by the pickup head 31 by a vacuum force or the like, and can be peeled from the dicing tape by driving the pickup head 31 in the +Z direction.

In step S203, the controller CNT delivers (transfers) the target first die 51 picked up by the pickup head 31 to the bonding head 423 of the bonding unit 4. More specifically, as shown in FIG. 1, the controller CNT arranges the pickup head 31 below the bonding head 423 by driving in the X direction the pickup head 31 picking up the target first die 51. The controller CNT then delivers the target first die 51 from the pickup head 31 to the bonding head 423 by driving the pickup head 31 in the +Z direction. When picking up the target first die 51 by the pickup head 31, the bonding surface 51a of the target first die 51 is oriented in the +Z direction and comes into contact with the pickup head 31. In contrast, when delivering the target first die 51 from the pickup head 31 to the bonding head 423, the bonding surface 51a of the target first die 51 needs to be oriented in the −Z direction. To do this, the pickup head 31 can be driven to rotate such that the target first die 51 is turned over (flip-chip) while being conveyed to the bonding head 423.

In this embodiment, an example in which the pickup head 31 directly conveys the target first die 51 to the bonding head 423 has been described, but the present invention is not limited to this. For example, when one or more conveyance mechanisms are provided on the conveyance path of the target first die 51 to the bonding head 423, the target first die 51 maybe conveyed to the bonding head 423 through a process of delivering the target first die 51 to the one or more conveyance mechanisms. A mechanism that performs a preprocess for the bonding process on the target first die 51 maybe provided inside the bonding apparatus 100. The preprocess is, for example, a process of applying an adhesive to the bonding surface 51a of the target first die 51 in bonding using an adhesive, or a process of activating the bonding surface 51a of the target first die 51 in hybrid bonding. As the preprocess, a washing process of the target first die 51 may be executed. The preprocess may be performed while conveying the target first die 51 to the bonding head 423.

By the above processes, the first wafer 6 is held by the stage 43, and the target first die 51 is held by the bonding head 423.

Subsequently, in step S103, the controller CNT performs die alignment using the die observation camera 431. In the die alignment, as shown in FIG. 3A, the die observation camera 431 is arranged below the target first die 51 held by the bonding head 423 by driving the wafer stage 43 on which the die observation camera 431 is mounted. The die observation camera 431 captures an image of the bonding surface 51a of the target first die 51, and the position of the pattern 501 provided on the bonding surface 51a of the target first die 51 is obtained based on the captured image.

Focus adjustment when capturing an image of the bonding surface 51a of the target first die 51 maybe performed by the focus adjustment mechanism of the die observation camera 431, or by driving the die observation camera 431 in the Z direction by the Z driving mechanism of the wafer stage 43. When the Z driving mechanism is provided on the bonding head 423, focus adjustment may be performed by driving the target first die 51 in the Z direction by the Z driving mechanism of the bonding head 423. In this embodiment, the alignment mark 502 is provided on the bonding surface 51a of the target first die 51, so the position of the pattern 501 of the target first die 51 can be obtained using the alignment mark 502. On the other hand, for a general die, an alignment mark is often arranged on a scribe line and removed together with the scribe line. In this case, the position of the pattern of the die may be obtained using a portion (to be sometimes referred to as a specifiable portion hereinafter) of the bonding surface that allows specifying the position of the pattern. As the specifiable portion, for example, the end of the array of electrodes (pads) or bumps arranged on the bonding surface, a region having an aperiodic array, or the outer edge (outer shape) of the die can be used.

For example, the controller CNT can measure the position of the pattern 501 of the target first die 51 by measuring the image position of the projected alignment mark 502 or specifiable portion with respect to the center of the image obtained by the die observation camera 431. The measurement of the position of the target first die 51 can include measurement of the rotation amount (rotation in the θZ direction) of the target first die 51. The rotation amount of the target first die 51 can be measured by, for example, obtaining the positions of a plurality of specifiable portions on the bonding surface 51a of the target first die 51 based on the image obtained by the die observation camera 431. The positions of the plurality of specifiable portions can be obtained based on a plurality of images obtained by individually capturing the specifiable portions while driving the die observation camera 431 by the wafer stage 43. Alternatively, when the entire target first die 51 falls within the visual field of image capturing of the die observation camera 431, the positions of the plurality of specifiable portions can be obtained from an image obtained by capturing the entire bonding surface 51a of the target first die 51 by the die observation camera 431. The rotation amount of the target first die 51 can be corrected by rotating the first wafer 6 by the wafer stage 43 in the bonding process. However, the measurement range of the interferometer 422 in the θZ direction is narrow. Thus, if the rotation amount of the target first die 51 is large, the target first die 51 is desirably rearranged on the bonding head 423 so as to correct the rotation amount of the target first die 51. When the target first die 51 is rearranged on the bonding head 423, the position of the target first die 51 needs to be measured again.

During execution of step S103, the surface position of the target first die 51 is preferably measured using a second height measurement means (not shown) that measures the surface position of the bonding surface 51a of the target first die 51. Since the thickness of the target first die 51 varies, the surface position of the target first die 51 is important to accurately manage (control) the gap between the first wafer 6 and the target first die 51 in the bonding process. Further, the heights of a plurality of positions on the bonding surface 51a of the target first die 51 (that is, the height distribution of the bonding surface 51a) may be measured to adjust the relative postures of the first wafer 6 and the target first die 51 based on the measurement result in the bonding process. The relative postures can be adjusted by a tilt mechanism mounted on the wafer stage 43 and/or the bonding head 423.

In step S104, the controller CNT determines, as an offset amount, an amount to offset the bonding position on the first wafer 6 (on the first substrate) to which the target first die 51 is to be bonded from the target region (design position). Here, in this embodiment, after the plurality of first dies 51 (first objects) are bonded to the first wafer 6, a process of pasting, to the first wafer 6 to which the plurality of first dies 51 are bonded, a second wafer (second substrate) with a plurality of second dies (second objects) bonded thereto is performed. This process may be understood as a process of bonding the plurality of dies 51 bonded to the first wafer 6 and the plurality of second dies bonded to the second wafer, and will sometimes be referred to as “pasting process” hereinafter. By this pasting process, a plurality of sets of one first die 51 and one second die, which are electrically connected, are formed. However, if the arrangement of the plurality of first dies 51 bonded to the first wafer 6 and the arrangement of the plurality of second dies bonded to the second wafer are deviated from each other, a set of the first die 51 and the second die with an electrical connection failure may be formed. Hence, in this embodiment, the offset amount is determined to satisfy a predetermined condition based on information representing the arrangement of the plurality of second dies on the second wafer. The predetermined condition can include a first condition to electrically connect each of the plurality of first dies 51 and the first wafer 6 after the bonding process to be described later is performed. The predetermined condition can further include a second condition to electrically connect each of the plurality of first dies 51 and a corresponding one of the plurality of second dies after the pasting process is performed. The offset amount can be defined as an amount including at least one of a shift amount and a rotation amount with respect to a target region (design position) on the first wafer 6. The offset amount may be understood as a deviation amount for deviating at least one of the position in the X and Y directions and the posture (rotation) in the θZ direction with respect to the target region (design position) on the first wafer 6. Note that details of determination of the offset amount will be described later.

In step S105, the controller CNT performs alignment between the first wafer 6 and the target first die 51 based on the offset amount determined in step S104. More specifically, the controller CNT drives the stage 43 to perform alignment between the first wafer 6 and the target first die 51 such that the target first die 51 is arranged at a position deviating from the target region (design position) on the first wafer 6 by the offset amount. The alignment can be performed based on the position of the pattern of the wafer 6 obtained in step S102 and the position of the pattern 501 of the target die 51 obtained in step S103. If the relative position between the first wafer 6 and the target first die 51 in the X and Y directions changes (shifts) in the bonding process to be described later, the first wafer 6 and the target first die 51 maybe aligned in consideration of the change amount of the relative position as well. The change amount of the relative position can be obtained in advance by experiment, simulation, or the like.

In step S106, the controller CNT bonds the target first die 51 to the first wafer 6 by narrowing the interval between the bonding head 423 and the wafer stage 43 (bonding process). The bonding process may be performed by driving the target first die 51 in the Z direction by the bonding head 423, or driving the first wafer 6 in the Z direction by the wafer stage 43. Alternatively, the bonding process may be performed by driving the target first die 51 and the first wafer 6 relatively in the Z direction by the bonding head 423 and the wafer stage 43. To accurately control the interval (gap) between the first wafer 6 and the target first die 51, it is preferable to provide a detector (for example, an encoder) that detects the position of the bonding head 423 and/or wafer stage 43 in the Z direction. Also, in the bonding process, ultrasonic waves may be applied to the bonding head 423 and/or the wafer stage 43 in a state in which the first wafer 6 and the target first die 51 are in contact with each other (that is, ultrasonic bonding may be applied). After bonding the first wafer 6 and the target first die 51, the controller CNT cancels the holding of the target die 51 by the bonding head 423 and widens the interval between the bonding head 423 and the wafer stage 43. Note that the bonding process may be understood to include the above-described alignment in step S105.

Here, to improve the alignment accuracy of the first wafer 6 and the target first die 51 even during execution of the bonding process, the relative position between the first wafer 6 and the target first die 51 in the X and Y directions can be controlled. In this case, the width of the mirror 432 in the Z direction is preferably so set as to irradiate the mirror 432 with light from the interferometer 422 even if the wafer stage 43 is driven in the Z direction. Also, a detector (for example, an encoder or a gap sensor) that detects the relative position between the bonding head 423 and the wafer stage 43 in the X and Y directions may be provided. In this case, feedback control of the relative position can be performed while the detector detects (monitors) the relative position between the bonding head 423 and the wafer stage 43 in the X and Y directions during execution of the bonding process. Note that if the first wafer 6 and the target first die 51 come into contact with each other, the position of the wafer stage 43 feedback-controlled based on the measurement result of the interferometer 422 is restrained. Hence, the control method of the relative position between the first wafer 6 and the target first die 51 in the X and Y directions is preferably switched before and after contact by, for example, stopping the feedback processing at the start of contact between the first wafer 6 and the target first die 51. In bump bonding, a process necessary for the bump bonding can be executed in step S106 by, for example, pressing the target first die 51 against the first wafer 6 at a predetermined pressure (pressing pressure).

In step S107, the controller CNT judges whether the first dies 51 are bonded to all target regions on the first wafer 6. Normally, several tens to several hundred semiconductor devices are formed as a plurality of target regions on one wafer, and a die can be bonded to each of the plurality of target regions. If a target region (next target region) to which the first die 51 is to be bonded next exists on the first wafer 6, the process advances to step S202. On the other hand, if no next target region exists on the first wafer 6, that is, the first dies 51 are bonded to all the plurality of target regions on the first wafer 6, the process advances to step S108.

In this embodiment, an example in which whether the next target region exists is judged after the bonding process, and the process returns to step S202 has been explained. However, the judgment of whether the next target region exists may be performed before the end of the bonding process. In this case, step S202 can be performed in parallel to execution of the bonding process. That is, in parallel to execution of the bonding process, the first die 51 to be bonded to the next target region is picked up from the dicing frame 5 (dicing tape). In a case where a plurality of types of dies are bonded to each target region (semiconductor device) on the first wafer 6, dies of one type are bonded to all the target regions of the first wafer 6 and then bonding of dies of the next type starts. At the start of bonding dies of the next type, the loading operation (step S201) of the dicing frame 5 on which dies of the next type are arranged is executed and then the die pickup in step S202 can be executed.

In step S108, using the wafer conveyance mechanism (not shown), the controller CNT unloads the first wafer 6 with the plurality of first dies 51 bonded thereto from the wafer stage 43 (chuck 433). There can be considered a case where the first wafer 6 is returned to the FOUP used for the loading of the first wafer 6 and a case where the first wafer 6 is returned to a container different from the FOUP. The first wafer 6 is preferably returned to another container because the thickness of the whole first wafer 6 to which the plurality of first dies 51 are bonded changes. The operation procedure of the bonding apparatus 100 for bonding the plurality of first dies 51 to one first wafer 6 has been described above. When bonding dies to each of a plurality of wafers, the flowchart of FIG. 4 is repeated.

Note that since the number of dies on the dicing frame 5 and the number of target regions on the wafer are generally different, loading of the wafer and loading of the dicing frame 5 do not synchronize in most cases. If the dies on the dicing frame 5 run out during bonding of the dies to one wafer, the next dicing frame 5 can be loaded into the bonding apparatus 100. On the other hand, if the dies remain on the dicing frame 5 even after the end of bonding the dies to one wafer, the remaining dies can be used for the next wafer.

### Offset Amount Determination Method

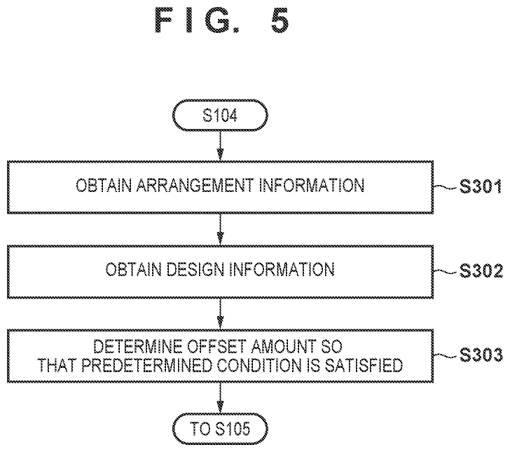

A method of determining the offset amount in step S104 described above will be described next. FIG. 5 is a flowchart showing a method of determining, as an offset amount, an amount to offset the bonding position on the first wafer 6 (on the first substrate) from the target region (design position). In this embodiment, the flowchart of FIG. 5 can be executed for the target first die 51 (that is, one target region on the first wafer 6) in step S104 of the flowchart shown in FIG. 4. However, the present invention is not limited to this, and the flowchart of FIG. 5 may be executed before the flowchart of FIG. 4 for each of the plurality of first dies 51 to be bonded to the first wafer 6 (that is, each of a plurality of target regions on the first wafer 6). An example in which the flowchart of FIG. 5 is executed by the controller CNT of the bonding apparatus 100 will be described below. However, the present invention is not limited to this, and the flowchart of FIG. 5 maybe executed by an information processing apparatus provided outside the bonding apparatus 100. In this case, the controller CNT can obtain information representing the offset amount determined by the external information processing apparatus from the external information processing apparatus. The external information processing apparatus can be formed by a computer including a processor such as a CPU and a storage such as a memory.

In step S301, the controller CNT obtains arrangement information representing the arrangement of a plurality of second dies (second objects) bonded to the second wafer (second substrate). The arrangement information may include information representing the position of an electrode provided on each of the plurality of second dies bonded to the second wafer. For example, the controller CNT compares the position of each second die bonded to the second wafer with the position (design position) of the second die on the second wafer in design. Hence, the controller CNT can obtain, as the arrangement information, information representing the deviation amount (a position deviation in the X and Y directions and a rotation deviation in the θZ direction) of each of the plurality of second dies on the second wafer from the design position. Note that the position of each second die bonded to the second wafer can be measured by an external measurement apparatus. However, each second die may be bonded to the second wafer by the above-described bonding apparatus 100, and in this case, the position of each second die may be measured using the die observation camera 431.

Here, the second wafer is a substrate to be pasted (bonded) to the first wafer 6 in the pasting process after the plurality of first dies 51 are bonded to the first wafer 6, as described above. Alignment between the first wafer 6 (first substrate) and the second wafer (second substrate) in the pasting process can be done based on a preset target positional relationship. More specifically, alignment between the first wafer 6 and the second wafer in the pasting process can be performed such that the plurality of target regions (design positions) on the first wafer 6 and the plurality of target regions (design positions) on the second wafer overlap (match). Also, alignment between the first wafer 6 and the second wafer in the pasting process may be performed such that the outer shape of the first wafer 6 and the outer shape of the second wafer overlap (match).

In step S302, the controller CNT obtains design information representing design positions (that is, the arrangement of the plurality of target regions) to which the plurality of first dies 51 are to be bonded on the first wafer 6 (first substrate). The design information may include information representing the position of an electrode provided in each of the plurality of target regions on the first wafer 6.

In step S303, based on the arrangement information obtained in step S301 and the design information obtained in step S302, the controller CNT determines the offset amount such that a predetermined condition is satisfied. As described above, the predetermined condition can include a first condition to electrically connect each first die 51 and the first wafer 6 after the bonding process is executed, and a second condition to electrically connect each first die 51 and a corresponding second die after the pasting process is executed. That is, based on the arrangement information and the design information, the controller CNT determines the offset amount within the position range in which the first die 51 and the second die, which correspond to each other, are electrically connected to satisfy the first condition and the second condition. Here, the first condition may include a condition that the electrodes of each first die 51 and the first wafer 6 (target region) are connected at least partially after the bonding process is executed. Also, the second condition may include a condition that the electrodes of each first die 51 and the second die corresponding to it are connected at least partially after the pasting process is executed.

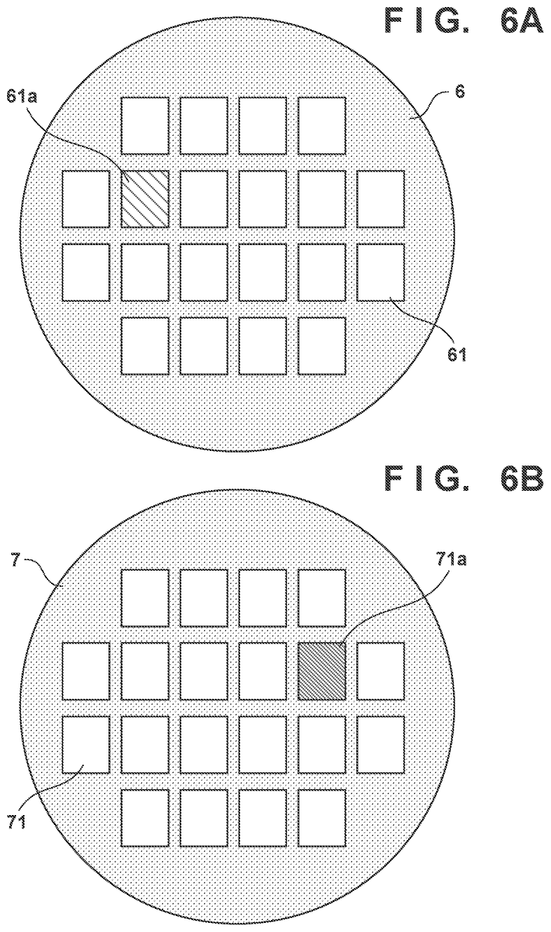

The offset amount will be described below. FIG. 6A shows a plurality of design positions 61 (target regions) to which the plurality of first dies 51 are to be bonded on the first wafer 6, and FIG. 6B shows a plurality of design positions 71 (target positions) to which the plurality of second dies are to be bonded on a second wafer 7. The plurality of design positions 71 on the second wafer 7 can be arranged to correspond to (match) the plurality of design positions 61 on the first wafer 6 when the second wafer 7 is turned over and pasted to the first wafer 6. That is, when the first wafer 6 and the second wafer 7 are pasted to each other, the design positions 61 on the first wafer 6 and the corresponding design positions 71 on the second wafer 7 overlap. As an example, when the first wafer 6 and the second wafer 7 are pasted to each other, a design position 61a on the first wafer 6 shown in FIG. 6A and a design position 71a on the second wafer 7 shown in FIG. 6B overlap.

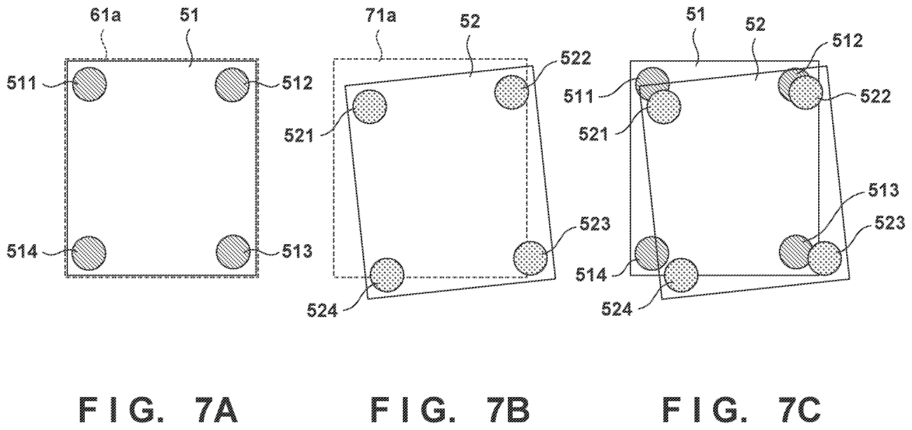

The offset amount when bonding the first die 51 to the design position 61a on the first wafer 6 will be described below with reference to FIGS. 7A to 7C, 8A to 8C, and 9A to 9C. For the descriptive convenience, FIGS. 7A to 7C, 8A to 8C, and 9A to 9C show a state seen through a second die 52 bonded to the second wafer 7.

FIGS. 7A to 7C show an example in which the second die 52 is bonded with a deviation to the design position 71a on the second wafer 7, and the first die 51 is bonded to the design position 61a on the first wafer 6 as designed. FIG. 7A shows the position deviation of the first die 51 with respect to the design position 61a on the first wafer 6, and FIG. 7B shows the position deviation of the second die 52 with respect to the design position 71a on the second wafer 7. FIG. 7C shows a state in which the first die 51 and the second die 52 are bonded. Note that since FIGS. 7A to 7C show an example in which the first die 51 is bonded to the design position 61a on the first wafer 6 as designed, a position deviation of the first die 51 with respect to the design position 61a on the first wafer 6 does not occur in FIG. 7A.

Electrodes 511 to 514 are provided on the bonding surface of the first die 51 (that is, the surface (back surface 51b) on the opposite side of the surface bonded to the first wafer 6) to be bonded to the second die 52. Also, electrodes 521 to 524 are provided, at positions corresponding to the electrodes 511 to 514 of the first die 51, on the bonding surface of the second die 52 to be bonded to the first die 51 (that is, the surface on the opposite side of the surface bonded to the second wafer 7). The electrode 511 of the first die 51 is an electrode that should electrically be connected to the electrode 521 of the second die 52. Similarly, the electrodes 512 to 514 of the first die 51 are electrodes that should electrically be connected to the electrodes 522 to 524 of the second die 52, respectively.

In the example shown in FIGS. 7A to 7C, as shown in FIG. 7B, the second die 52 is bonded with a deviation to the design position 71a on the second wafer 7. In this example, if the first die 51 is bonded as designed to the design position 61a on the first wafer 6, as shown in FIG. 7A, an electrode pair without electrical connection may be formed between the first die 51 and the second die 52, as shown in FIG. 7C. In FIG. 7C, an electrode pair formed by the electrode 513 of the first die 51 and the electrode 523 of the second die 52 has no electrical connection.

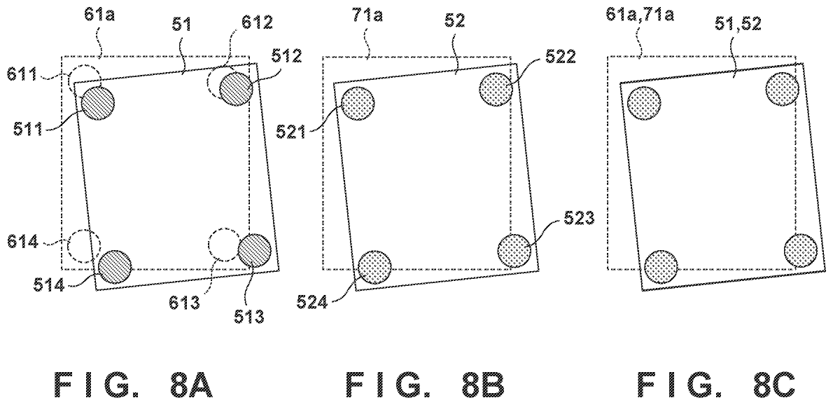

FIGS. 8A to 8C show an example in which the second die 52 is bonded with a deviation to the design position 71a on the second wafer 7, and the first die 51 is bonded to the design position 61a on the first wafer 6 with the same deviation as the deviation of the second die 52 to the design position 71a on the second wafer 7. FIG. 8A shows the position deviation of the first die 51 to the design position 61a on the first wafer 6, and FIG. 8B shows the position deviation of the second die 52 to the design position 71a on the second wafer 7. FIG. 8C shows a state in which the first die 51 and the second die 52 are bonded. In the example shown in FIGS. 8A to 8C, as shown in FIG. 8C, the first die 51 and the second die 52 overlap each other, and the electrodes 511 to 514 of the first die 51 and the electrodes 521 to 524 of the second die 52 are electrically connected. In this case, however, as shown in FIG. 8A, among electrodes 611 to 614 provided at the design position 61a (target region) on the first wafer 6, there may be an electrode (the electrode 614 in the example shown in FIG. 8A) that is not connected to an electrode of the first die 51. Note that in FIG. 8A, for the descriptive convenience, even on the bonding surface of the first die 51 bonded to the first wafer 6, the electrodes are provided at the same positions as the electrodes 511 to 514 on the bonding surface of the first die 51 to be bonded to the second die 52.

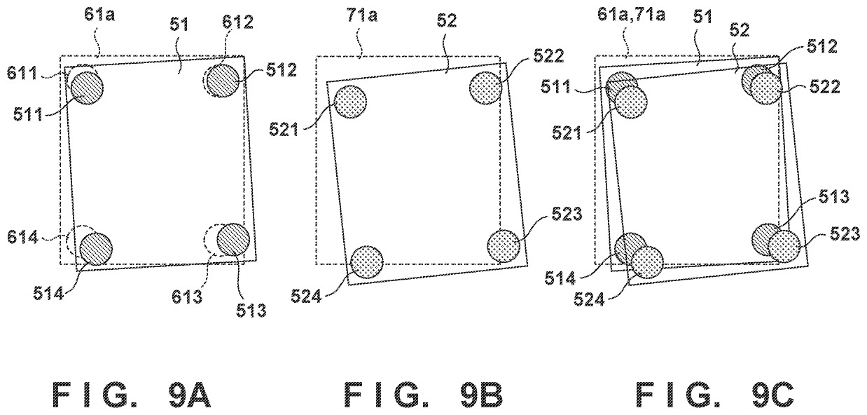

FIGS. 9A to 9C show an example in which the second die 52 is bonded with a deviation to the design position 71a on the second wafer 7, and the first die 51 is bonded to the design position 61a on the first wafer 6 with the same deviation as the offset amount determined by the flowchart of FIG. 5. FIG. 9A shows the position deviation of the first die 51 to the design position 61a on the first wafer 6, and FIG. 9B shows the position deviation of the second die 52 to the design position 71a on the second wafer 7. FIG. 9C shows a state in which the first die 51 and the second die 52 are bonded. In the example shown in FIGS. 9A to 9C, the offset amount is determined to satisfy the first condition and the second condition in accordance with the flowchart of FIG. 5, and the first die 51 is bonded to the design position 61a on the first wafer 6 with the same deviation as the offset amount. Hence, the electrodes of the first wafer 6 and the first die 51 can electrically be connected, as shown in FIG. 9A, and the electrodes of the first die 51 and the second die 52 can electrically be connected, as shown in FIG. 9C.

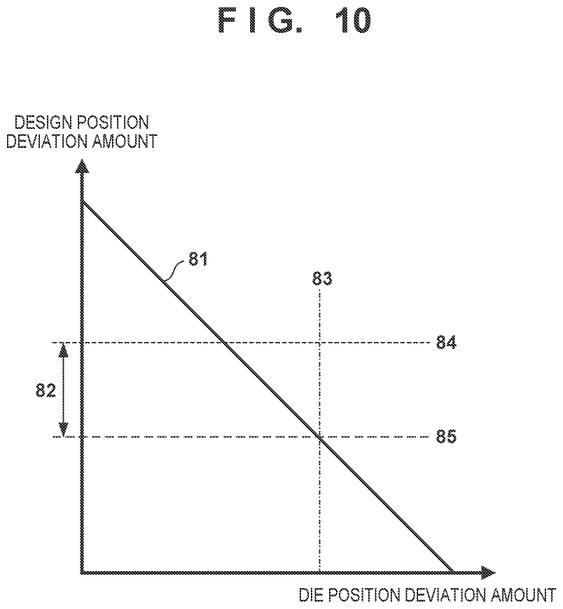

FIG. 10 is a view showing a relationship 81 between the position deviation amount of the first die 51 with respect to the second die 52 and the position deviation amount of the first die 51 with respect to the design position 61a on the first wafer 6. The relationship 81 shown in FIG. 10 can be created in advance based on information representing design values or measurement values such as the dimensions of the first die 51, the dimensions of the electrodes provided on the first die 51, the dimensions of the second die 52, and the dimensions of the electrodes provided on the second die 52 in addition to the arrangement information. The arrangement information is information representing the arrangement of the plurality of second dies 52 bonded to the second wafer 7 and can include information representing the position of the second die 52 with respect to the design position 71a on the second wafer 7, as described above. Here, the position deviation amount of the first die 51 with respect to the second die 52 includes at least one of the shift amount and the rotation amount of the first die 51 with respect to the second die 52, and will sometime be referred to as “die position deviation amount” hereinafter. Also, the deviation amount of the first die 51 with respect to the design position 61a on the first wafer 6 includes at least one of the shift amount and the rotation amount of the first die 51 with respect to the design position 61a, and will sometimes be referred to as “design position deviation amount” hereinafter.

The abscissa of the graph shown in FIG. 10 indicates the die position deviation amount, and the die position deviation amount increases toward the right side. On the other hand, the ordinate of the graph shown in FIG. 10 indicates the design position deviation amount, and the design position deviation amount increases toward the upper side. FIG. 10 shows a limit value 83 of the die position deviation amount, and the first die 51 and the second die 52 cannot electrically be connected on the right side of the limit value 83. The value on the ordinate at the intersection between the relationship 81 and the limit value 83 is a limit value 85 of the design position deviation amount at which the first die 51 and the second die 52 can electrically be connected. That is, the first die 51 and the second die 52 cannot electrically be connected on the lower side of the limit value 85, and the condition that the design position deviation amount is located on the higher side of the limit value 85 can be the first condition. Furthermore, FIG. 10 shows a limit value 84 of the design position deviation amount. That is, the first wafer 6 and the first die 51 cannot electrically be connected on the upper side of the limit value 84, and the condition that the design position deviation amount is located on the lower side of the limit value 84 can be the second condition. Hence, the range between the limit value 84 and the limit value 85 is a position range 82 of the first die 51 to satisfy the first condition and the second condition, and the controller CNT determines the offset amount within the position range 82. For example, the controller CNT preferably determines the median within the position range 82 as the offset amount unless other constraint conditions exist.

As described above, in this embodiment, the offset amount is determined to satisfy the first condition and the second condition described above, and the first die 51 is bonded to a position deviating from the design position on the first wafer 6 by the offset amount. This makes it possible to electrically connect the first wafer 6 and the first die 51 after a bonding step, and also electrically connect the first die 51 and the second die 52 after a pasting step.

### <Embodiment of Article Manufacturing Method>

A method of manufacturing an article (a semiconductor IC element, a liquid crystal display element, a MEMS, or the like) using the above-described bonding apparatus will be described. The article manufacturing method according to the embodiment of the present invention is suitable for manufacturing an article, for example, a microdevice such as a semiconductor device or an element having a fine structure. The article manufacturing method according to this embodiment includes a step of bonding each of a plurality of first objects to a first substrate using the above-described bonding apparatus or bonding method, a step of processing the first substrate to which the plurality of first objects are bonded, and a step of manufacturing an article from the processed first substrate. The step of processing the first substrate to which the plurality of first objects are bonded can include a step of pasting (bonding) a plurality of second objects which are bonded to a second substrate, to the plurality of first objects bonded to the first substrate. The manufacturing method also includes other known processes (for example, probing, dicing, bonding, and packaging). The article manufacturing method according to this embodiment is advantageous in at least one of the performance, quality, productivity, and production cost of the article, as compared to conventional methods.

### <Other Embodiments>

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-005316 filed on Jan. 17, 2023, which is hereby incorporated by reference herein in its entirety.

What is claimed is:

1. A bonding method of bonding each of a plurality of first objects to a first substrate, comprising:
determining, as an offset amount, an amount to offset a bonding position on the first substrate from a design position for each of the plurality of first objects; and
bonding each of the plurality of first objects to the first substrate based on the offset amount determined in the determining,
wherein after the bonding, a process of bonding a plurality of second objects which are bonded to a second substrate, to the plurality of first objects bonded to the first substrate is performed,
wherein in the determining, the offset amount is determined to satisfy a predetermined condition based on arrangement information representing an arrangement of the plurality of second objects on the second substrate, and
wherein the predetermined condition includes a first condition to electrically connect each of the plurality of first objects and the first substrate after the bonding is performed, and a second condition to electrically connect each of the plurality of first objects and a corresponding one of the plurality of second objects after the process is performed.

2. The method according to claim 1, wherein the offset amount includes at least one of a shift amount and a rotation amount with respect to the design position on the first substrate.

3. The method according to claim 1, wherein in the determining, a median within a position range of the first objects, which can satisfy the first condition and the second condition, is determined as the offset amount.

4. The method according to claim 1, wherein the arrangement information includes information representing at least one of a position and rotation of each of the plurality of second objects on the second substrate.

5. The method according to claim 1, wherein alignment between the first substrate and the second substrate in the process is performed based on a preset target positional relationship between the first substrate and the second substrate.

6. An article manufacturing method comprising:
bonding each of a plurality of first objects to a first substrate using a bonding method defined in claim 1;
processing the first substrate to which the plurality of first objects are bonded; and
manufacturing an article from the processed first substrate.

7. A bonding apparatus comprising:
a bonder configured to bond each of a plurality of first objects to a first substrate; and
a controller configured to determine, as an offset amount, an amount to offset a bonding position on the first substrate from a design position for each of the plurality of first objects, and control bonding of each of the plurality of first objects to the first substrate by the bonder based on the offset amount,
wherein after the bonding, a process of bonding a plurality of second objects which are bonded to a second substrate, to the plurality of first objects bonded to the first substrate is performed,
wherein the controller determines the offset amount to satisfy a predetermined condition based on arrangement information representing an arrangement of the plurality of second objects on the second substrate, and
wherein the predetermined condition includes a first condition to electrically connect each of the plurality of first objects and the first substrate after the bonding is performed, and a second condition to electrically connect each of the plurality of first objects and a corresponding one of the plurality of second objects after the process is performed.

8. A determination method of determining, as an offset amount, an amount to offset a bonding position on a first substrate from a design position for each of a plurality of first objects which are bonded to the first substrate,
wherein after each of the plurality of first objects is bonded to the first substrate, a process of bonding a plurality of second objects are bonded to a second substrate, to the plurality of first objects bonded to the first substrate is performed,
wherein the determination method includes determining the offset amount to satisfy a predetermined condition based on arrangement information representing an arrangement of the plurality of second objects on the second substrate, and
wherein the predetermined condition includes a first condition to electrically connect each of the plurality of first objects and the first substrate after the bonding is performed, and a second condition to electrically connect each of the plurality of first objects and a corresponding one of the plurality of second objects after the process is performed.

9. An information processing apparatus for executing a determination method defined in claim 8.

10. A non-transitory computer-readable storage medium storing a program for causing a computer to execute a determination method according to claim 8.
